(19) United States
(12) Patent Application Publication
(10) Pub. No.: US 2019/0258153 A1
(43) Pub. Date: Aug. 22, 2019

(54) METHOD FOR PROCESSING A MASK SUBSTRATE TO ENABLE BETTER FILM QUALITY

(71) Applicant: Applied Materials, Inc., Santa Clara, CA (US)

(72) Inventors: Srinivas D. NEMANI, Sunnyvale, CA (US); Ellie Y. YIEH, San Jose, CA (US); Mei-Yee SHEK, Palo Alto, CA (US)

(21) Appl. No.: 16/262,102

(22) Filed: Jan. 30, 2019

Related U.S. Application Data
(60) Provisional application No. 62/633,930, filed on Feb. 22, 2018.

(51) Int. Cl. G03F 1/22; G03F 1/26

(52) U.S. Cl. CPC G03F 1/22; G03F 1/26

(57) ABSTRACT

The present disclosure provides methods for forming a material layer in a film stack for manufacturing a photomask in EUV applications and phase shift and binary photomask applications. In one example, a method for forming a dielectric material on a substrate includes supplying an oxygen containing gas mixture on a substrate in a processing chamber, the substrate comprising a dielectric material disposed on an optically transparent silicon containing material, maintaining the oxygen containing gas mixture in the processing chamber at a process pressure at greater than 2 bar, and thermally treating the dielectric material in the presence of the oxygen containing gas mixture.

### CROSS-REFERENCE TO RELATED APPLICATIONS

This application claims benefit of U.S. Provisional Application Ser. No. 62/633,930 filed Feb. 22, 2018 (Attorney Docket No. APPM/44014895L), which is incorporated by reference in its entirety.

### BACKGROUND

### Field

Embodiments of the present invention generally relate to a method for forming a material layer in a film stack that may be utilized for both phase shift and binary photomask fabrication and EUV photomask fabrication.

### Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that comprise each completed chip. Thus, any defects in the mask may be transferred to the chip, potentially adversely affecting performance. Defects that are severe enough may render the mask completely useless. Typically, a set of 15 to 30 masks is used to construct a chip and can be used repeatedly.

A photomask is typically a glass or a quartz substrate giving a film stack having multiple layers, including an absorber layer, capping layer and a photomask shift mask layer disposed thereon. When manufacturing the photomask layer, a photoresist layer is typically disposed on the film stack to facilitate transferring features into the film stack during the subsequently patterning processes. During the patterning process, the circuit design is written onto the photomask by exposing portions of the photoresist to extreme ultraviolet light or ultraviolet light, making the exposed portions soluble in a developing solution. The soluble portion of the resist is then removed, allowing the exposed underlying film stack being etched. The etch process removes the film stack from the photomask at locations where the resist was removed, i.e., the exposed film stack is removed.

With the reduction of critical dimensions (CD), present optical lithography is approaching a technological limit at the 45 nanometer (nm) technology node. Next generation lithography (NGL) is expected to replace the conventional optical lithography method, for example, in the 32 nm technology node and beyond. There are several NGL candidates, such as extreme ultraviolet (EUV) lithography (EUVL), electron projection lithography (EPL), ion projection lithography (IPL), nano-imprint, and X-ray lithography. Among these, EUVL is the most likely successor due to the fact that EUVL has most of the properties of optical lithography, which is a more mature technology as compared with other NGL methods.

Accordingly, a new film scheme is being developed so as to work with the EUV technology to facilitate forming the photomask with desired features disposed thereon. The film stack may include multiple layers with different and new materials. However, different materials with diverse qualities often result in poor integration in the film stack. Thus, developing suitable materials with proper film qualities has becoming an important challenge for fabricating the photomask for EUV technology.

Thus, there is a need for materials layer suitable for using in a film stack for forming a photomask in EUV technology and phase shift and binary photomask applications.

### SUMMARY

The present disclosure provides methods for forming a material layer in a film stack for manufacturing a photomask in EUV applications and phase shift and binary photomask applications. In one example, a method for forming a dielectric material on a substrate includes supplying an oxygen containing gas mixture on a substrate in a processing chamber, the substrate comprising a dielectric material disposed on an optically transparent silicon containing material, maintaining the oxygen containing gas mixture in the processing chamber at a process pressure at greater than 2 bar, and thermally treating the dielectric material in the presence of the oxygen containing gas mixture.

In another example, a method for densifying a dielectric layer disposed on a substrate includes thermally treating a dielectric layer disposed on a glass substrate at a pressure greater than 2 bar, and maintaining a substrate temperature less than 400 degrees Celsius during thermally treating the dielectric layer.

In yet another example, a method for densifying a dielectric layer disposed on a substrate includes forming a dielectric layer on a glass substrate by a flowable chemical vapor deposition process, curing the dielectric layer at a substrate temperature less than 400 degrees Celsius, and thermally treating the dielectric layer on the glass substrate at a pressure greater than 2 bar while maintaining the substrate temperature less than 400 degrees Celsius.

### DETAILED DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

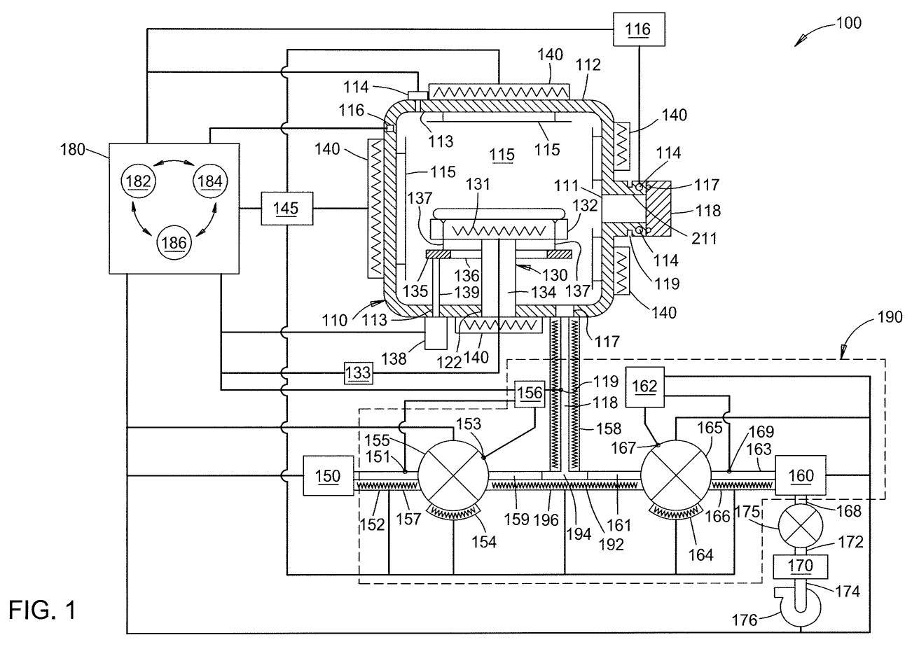

FIG. 1 is a simplified front cross-sectional view of a processing chamber with a cassette disposed therein in accordance with some embodiments;

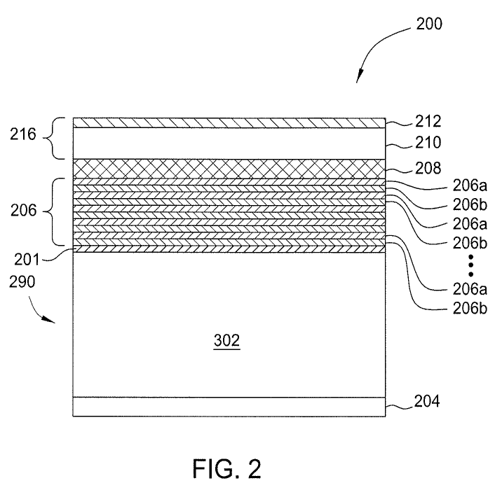

FIG. 2 depicts one embodiment of a film stack utilized to form an EUV photomask in accordance with some embodiments;

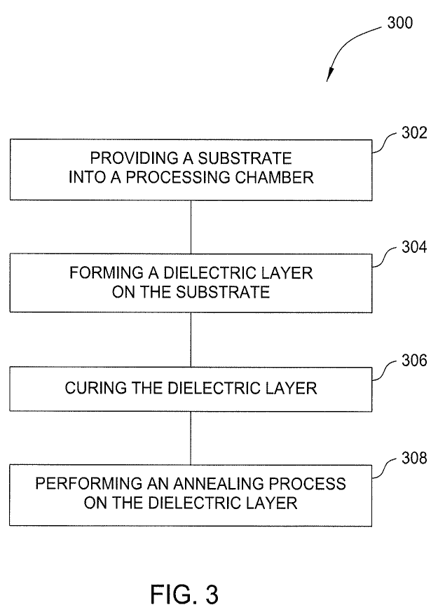

FIG. 3 depicts a flow diagram of a method for manufacturing a material layer utilized to form an EUV photomask in accordance with some embodiments;

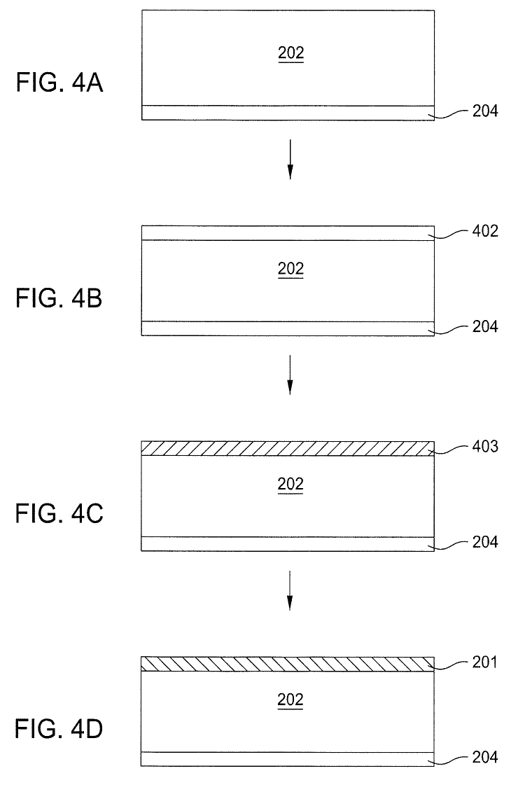

FIGS. 4A-4D depict one embodiment of a sequence for manufacturing the material layer of FIG. 3 in accordance with some embodiments.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

Embodiments of the present invention provide a method and apparatus for forming a material on a glass substrate for manufacturing a photomask. More specifically, the disclosure relates to methods of forming a dielectric layer on a glass substrate and/or a photomask substrate with improved substrate integrity. In one embodiment, the dielectric layer formed on the glass substrate may assist smoothing the surface of the glass substrate. By utilizing a high pressure annealing process, such as pressure greater than 2 bar, the dielectric layer may be densified to provide a smooth surface as well as high film density.

FIG. 1 is a simplified front cross-sectional view of a single-substrate processing chamber 100 for a high-pressure annealing process of a single substrate. The single-substrate processing chamber 100 has a body 110 with an outer surface 112 and an inner surface 113 that encloses an internal volume 115. In some embodiments such as in FIG. 1, the body 110 has an annular cross section, though in other embodiments the cross-section of the body 110 may be rectangular or any closed shape. The outer surface 112 of the body 110 may be made from a corrosion resistant steel (CRS), such as but not limited to stainless steel. One or more heat shields 125 are disposed on the inner surface 113 of the body 110 that prevents heat loss from the single-substrate processing chamber 100 into the outside environment. The inner surface 113 of the body 110 as well as the heat shields 125 may be made from nickel-based steel alloys that exhibit high resistance to corrosion, such as but not limited to HASTELLOY®, ICONEL®, and MONEL®.

A substrate support 130 is disposed within the internal volume 115. The substrate support 130 has a stem 134 and a substrate-supporting member 132 held by the stem 134. The stem 134 passes through a passage 122 formed through the chamber body 110. A rod 139 connected to an actuator 138 passes through a second passage 123 formed through the chamber body 110. The rod 139 is coupled to a plate 135 having an aperture 136 accommodating the stem 134 of the substrate support 130. Lift pins 137 are connected to the substrate-supporting member 132. The actuator 138 actuates the rod 139 such that the plate 135 is moved up or down to connect and disconnect with the lift pins 137. As the lift pins 137 are raised or lowered, the substrate-supporting member 132 is raised or lowered within the internal volume 115 of the chamber 100. The substrate-supporting member 132 has a resistive heating element 131 embedded centrally within. A power source 133 is configured to electrically power the resistive heating element 131. The operation of the power source 133 as well as the actuator 138 is controlled by a controller 180.

The single-substrate processing chamber 100 has an opening 111 on the body 110 through which one or more substrates 120 can be loaded and unloaded to and from the substrate support 130 disposed in the internal volume 115. The opening 111 forms a tunnel 121 on the body 110. A slit valve 128 is configured to sealably close the tunnel 121 such that the opening 111 and the internal volume 115 can only be accessed when the slit valve 128 is open. A high-pressure seal 127 is utilized to seal the slit valve 128 to the body 110 in order to seal the internal volume 115 for processing. The high-pressure seal 127 may be made from a polymer, for example a fluoropolymer, such as but not limited to a perfluoroelastomer and polytetrafluoroethylene (PTFE). The high-pressure seal 127 may further include a spring member for biasing the seal to improve seal performance. A cooling channel 124 is disposed on the tunnel 121 adjacent to the high-pressure seals 127 in order to maintain the high-pressure seals 127 below the maximum safe-operating temperature of the high-pressure seals 127 during processing. A cooling agent from a cooling fluid source 126, such as but not limited to an inert, dielectric, and high-performance heat transfer fluid, may be circulated within the cooling channel 124. The flow of the cooling agent from the cooling fluid source 126 is controlled by the controller 180 through feedback received from a temperature sensor 116 or a flow sensor (not shown). An annular-shaped thermal choke 129 is formed around the tunnel 221 to prevent the flow of heat from the internal volume 115 through the opening 111 when the slit valve 128 is open.

The single-substrate processing chamber 100 has a port 117 through the body 110, which is fluidly connected to a fluid circuit 190 connecting the gas panel 150, the condenser 160 and the port 117. The fluid circuit 190 has a gas conduit 192, a source conduit 157, an inlet isolation valve 155, an exhaust conduit 163, and an outlet isolation valve 165. A number of heaters 196, 158, 152, 154, 164, 166 are interfaced with different portions of the fluid circuit 190. A number of temperature sensors 151, 153, 119, 167 and 169 are also placed at different portions of the fluid circuit 190 to take temperature measurements and send the information to the controller 180. The controller 180 uses the temperature measurement information to control the operation of the heaters 152, 154, 158, 196, 164, and 166 such that the temperature of the fluid circuit 190 is maintained at a temperature above the condensation point of the processing fluid disposed in the fluid circuit 190 and the internal volume 115.

The gas panel 150 is configured to provide a processing fluid under pressure the internal volume 115. The pressure of the processing fluid introduced into the internal volume 115 is monitored by a pressure sensor 114 coupled to the body 110. The condenser 160 is fluidly coupled to a cooling fluid source (not shown) and configured to condense the gas phase processing fluid exiting the internal volume 115 through the gas conduit 192. The condensed processing fluid is then removed by the pump 176. One or more heaters 140 are disposed on the body 110 and configured to heat the internal volume 115 within the single-substrate processing chamber 100. The heaters 140, 152, 154, 158, 196, 164, and 166 maintain the processing fluid within the fluid circuit 190 in a gaseous phase while the outlet isolation valve 165 to the condenser 160 is open to prevent condensation within the fluid circuit.

The controller 180 controls the operation of the single-substrate processing chamber 100. The controller 180 controls the operation of the gas panel 150, the condenser 160, the pump 170, the inlet isolation valve 155, the outlet isolation valve 165, the power sources 133 and 145. The controller 180 is also communicatively connected to the temperature sensor 116, the pressure sensor 114, the actuator 138, the cooling fluid source 126 and the temperature reading devices 156 and 162.

The processing fluid may comprise an oxygen-containing and/or nitrogen-containing gas, such as oxygen, dry steam, water, hydrogen peroxide, and/or ammonia may be utilized. Alternatively or in addition to the oxygen-containing and/or nitrogen-containing gases, the processing fluid may comprise a silicon-containing gas. Examples of the silicon-containing gas include organosilicon, tetraalkyl orthosilicate gases and disiloxane. Organosilicon gases include gases of organic compounds having at least one carbon-silicon bond. Tetraalkyl orthosilicate gases include gases consisting of four alkyl groups attached to an SiO₄⁴⁻ ion. More particularly, the one or more gases may be (dimethylsilyl)(trimethylsilyl)methane ((Me)₃SiCH₂SiH(Me)₂), hexamethyldisilane ((Me)₃SiSi(Me)₃), trimethylsilane ((Me)₃SiH), trimethylsilylchloride ((Me)₃SiCl), tetramethylsilane ((Me)₄Si), tetraethoxysilane ((EtO)₄Si), tetramethoxysilane ((MeO)₄Si), tetrakis-(trimethylsilyl)silane ((Me₃Si)₄Si), (dimethylamino)dimethyl-silane ((Me₂N)SiHMe₂) dimethyldiethoxysilane ((EtO)₂Si(Me)₂), dimethyl-dimethoxysilane ((MeO)₂Si(Me)₂), methyltrimethoxysilane ((MeO)₃Si(Me)), dimethoxytetramethyl-disiloxane (((Me)₂Si(OMe))₂O), tris(dimethylamino)silane ((Me₂N)₃SiH), bis(dimethylamino)methylsilane ((Me₂N)₂CH₃SiH), disiloxane ((SiH₃)₂O), and combinations thereof.

During processing of the substrates 120, an environment of the high-pressure region 115 is maintained at a temperature and pressure that maintains the processing fluid within the high-pressure region in a vapor phase. Such pressure and temperature is selected based on the composition of the processing fluid. In the case of steam, the temperature and pressure is held at a condition that maintains the steam in a dry steam state. In one example, high-pressure region 115 is pressurized to a pressure greater than atmosphere, for example greater than about 2 bars. In another example, high-pressure region 115 is pressurized to a pressure from between about 10 and about 180 bars, such as from between about 20 and about 100 bars. In another example, the high-pressure region 115 is pressurized to a pressure up to about 200 bars. During processing, the high-pressure region 115 is also maintained at a high temperature, for example, a temperature exceeding 225 degrees Celsius (limited by the thermal budget of the substrates disposed on the cassette), such as between about 300 degrees Celsius and about 450 degrees Celsius.

FIG. 2 depicts an exemplary embodiment wherein the dielectric layer 201 may be utilized. The dielectric layer 201 may be an interfacial layer disposed between a substrate 202 and a film stack 200. As depicted in FIG. 2, the substrate 202 may be an optically transparent silicon based material or silicon containing material, such as quartz (i.e., silicon dioxide (SiO₂)) or glass material. A dielectric layer 201 is disposed on the substrate 202 having a film stack 200 further disposed thereon. The film stack 200 disposed on the substrate 202 that may be utilized to form desired features in the film stack 200 for fabricating a photomask suitable for EUV applications.

The dielectric layer 201 is formed on the substrate 202 to assist smoothing the surface of the substrate 202. As shown in the exemplary embodiment depicted in FIG. 2, the substrate 202 may be a quartz substrate (i.e., low thermal expansion silicon dioxide (SiO₂)) layer. The dielectric layer 201 formed on the substrate 202 to assist providing a planar surface of the substrate 202, if there are any pits, defects, or uneven surface structures from the substrate 202. The substrate 202 may have a rectangular shape having sides between about 5 inches to about 9 inches in length. The substrate 202 may be between about 0.15 inches and about 0.25 inches thick. In one embodiment, the substrate 202 is about 0.25 inches thick. An optional chromium containing layer 204, such as a chromium nitride (CrN) layer may be disposed to a backside of the substrate 202 as needed.

An EUV reflective multi-material layer 206 is disposed on the dielectric layer 201 on the substrate 202. The reflective multi-material layer 206 may include at least one molybdenum layer 206a and at least one silicon layer 206b. Although the embodiment depicted in FIG. 2 shows five pairs of molybdenum layer 206a and a silicon layer 206b (alternating molybdenum layers 206a and the silicon layers 206b repeatedly formed on the substrate 202), it is noted that number of molybdenum layers 206a and the silicon layers 206b may be varied based on different process needs. In one particular embodiment, forty pairs of molybdenum layers 206a and the silicon layers 206b may be deposited to form the reflective multi-material layer 206. In one embodiment, the thickness of each single molybdenum layer 206a may be controlled at between about 1 Å and about 10 Å, such as about 3 Å, and the thickness of the each single silicon layer 206b may be controlled at between about 1 Å and about 10 Å, such as about 4 Å. The reflective multi-material layer 206 may have a total thickness between about 10 Å and about 500 Å. The reflective multi-material layer 206 may have an EUV light reflectivity of up to 70% at 13.5 nm wavelength. The reflective multi-material layer 206 may have a total thickness between about 70 nm and about 140 nm.

Subsequently, a capping layer 208 is disposed on the reflective multi-material layer 206. The capping layer 208 may be fabricated by a metallic material, such as ruthenium (Ru) material, zirconium (Zr) material, or any other suitable material. In the embodiment depicted in FIG. 2, the capping layer 208 is a ruthenium (Ru) layer. The capping layer 208 may have a thickness between about 1 nm and about 10 nm.

An absorber layer 216 may then be disposed on the capping layer 208. The absorber layer 216 is an opaque and light-shielding layer configured to absorb a portion of the light generated during the lithography process. The absorber layer 216 may be in form of a single layer or a multi-layer structure, such as including a self-mask layer 212 disposed on a bulk absorber layer 210, as the embodiments depicted in FIG. 2. The absorber layer 216 may be a metal containing layer, e.g., a chromium containing layer, such as a Cr metal, chromium oxide (CrOₓ), chromium nitride (CrN) layer, chromium oxynitride (CrON), or multilayer with these materials, as needed. In one embodiment, the absorber layer 216 has a total film thickness between about 50 nm and about 200 nm. The total thickness of the absorber layer 216 advantageously facilitates meeting the strict overall etch profile tolerance for EUV masks in sub-45 nm technology node applications.

In one embodiment, the bulk absorber layer 210 may comprise tantalum-based materials with essentially no oxygen, for example tantalum silicide based materials, such as TaSi or TaSiN, nitrogenized tantalum boride-based materials, such as TaBN, and tantalum nitride-based materials, such as TaN. The self-mask layer 212 may be fabricated from a tantalum and oxygen-based materials. The composition of the self-mask layer 212 corresponds to the composition of the bulk absorber layer 210 and may comprise oxidized and nitrogenized tantalum and silicon based materials, such as TaSiON, when the bulk absorber layer 210 comprises TaSi or TaSiN; tantalum boron oxide based materials, such as TaBO, when the bulk absorber layer 210 comprises TaBN; and oxidized and nitrogenized tantalum-based materials, such as TaON or TaO, when the bulk absorber layer 210 comprises TaN.

FIG. 3 is a flow diagram of one example of a method 300 for forming a dielectric layer, such as the dielectric layer 201 depicted in FIG. 2, which may be utilized for EUV photomask applications. FIGS. 4A-4D are cross-sectional views of a portion of a composite substrate corresponding to various stages of the method 300.

The method 300 begins at operation 302 by providing a substrate as shown in FIG. 4A. The substrate 202 may be the substrate 202 depicted in FIG. 2. As discussed above, the substrate 202 may be a quartz substrate (i.e., low thermal expansion silicon dioxide (SiO₂)) layer. The substrate 202 may have a rectangular shape having sides between about 5 inches to about 9 inches in length. The substrate 202 may be between about 0.15 inches and about 0.25 inches thick. In one embodiment, the substrate 202 is about 0.25 inches thick. An optional chromium containing layer 204, such as a chromium nitride (CrN) layer may be disposed to a backside of the substrate 202 as needed.

At operation 304, a dielectric material 402 may be deposited by using suitable deposition techniques, as shown in FIG. 4B. In one example, the dielectric material 402 may be formed by a flowable chemical vapor deposition process. In one embodiment, the dielectric material 402 is a silicon containing material deposited by a deposition gas mixture supplied in a process chamber where the substrate 202 is transferred to. Suitable examples of the silicon containing material include silicon oxide (SiO₂), silicon oxycarbide (SiOC), silicon carbide (SiC), silicon nitride (SiN), silicon oxynitride (SiON), amorphous silicon, and nitrogen containing silicon carbide (SiCN), among others. In some examples, high-k material layers include hafnium dioxide (HfO₂), zirconium dioxide (ZrO₂), hafnium silicon oxide (HfSiO₂), hafnium aluminum oxide (HfAlO), zirconium silicon oxide (ZrSiO₂), tantalum dioxide (TaO₂), aluminum oxide, aluminum doped hafnium dioxide, bismuth strontium titanium (BST), and platinum zirconium titanium (PZT), among others, may also be utilized to form the dielectric material 402.

In one embodiment, the dielectric material 402 is a silicon oxide material. The deposition gas mixture utilized to form the dielectric material 402 may include a dielectric material precursor and a processing precursor. Suitable examples of the dielectric material precursor include silane, disilane, methylsilane, dimethylsilane, trimethylsilane, tetramethylsilane, tetraethoxysilane (TEOS), triethoxysilane (TES), octamethylcyclotetrasiloxane (OMCTS), tetramethyl-disiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SiₓN_{y}H_{z} containing precursors, such as sillyl-amine and its derivatives including trisillylamine (TSA) and disillylamine (DSA), SiₓN_{y}H_{z}O_{zz} containing precursors, SiₓN_{y}H_{z}Cl_{zz} containing precursors, or combinations thereof. In one exemplary embodiment, the silicon containing precursor used for depositing the dielectric material 408 is trisillylamine (TSA). In addition, suitable examples of the processing precursors may include a nitrogen containing precursor. Suitable examples of the nitrogen containing precursor includes a H₂/N₂ mixture, N₂, NH₃, NH₄OH, N₂, NₓH_{y} compounds including N₂H₄ vapor, NO, N₂O, NO₂ and the like. Furthermore, the processing precursors may also include hydrogen-containing compounds, oxygen-containing compounds or combinations thereof. Examples of suitable processing precursors include one or more of compounds selected from the group comprising of H₂, a H₂/N₂ mixture, O₃, O₂, H₂O₂, water vapor, or combinations thereof. The processing precursors may be plasma excited, such as in the RPS unit, to include N* and/or H* and/or O* containing radicals or plasma, for example, NH₃, NH₂*, NH*, N*, H*, O*, N*O*, or combinations thereof. The processing precursor may alternatively, include one or more of the precursors as needed.

In one embodiment, the substrate temperature during the deposition process is maintained at a predetermined range. In one embodiment, the substrate temperature is maintained at less than about 200 degrees Celsius, such as less than 100 degrees Celsius so as to allow the dielectric material 408 formed on the substrate to be flowable to reflow and fill within the trenches 406. It is believed that relative lower substrate temperature, such as less than 100 degrees Celsius, can assist maintaining the film initially formed on the substrate surface in a liquid-like flowable state, so as to preserve the flowability and viscosity of the resultant film formed thereon. As the resultant film is formed on the substrate having a certain degree of flowability and viscosity, the bonding structure of the film may be transformed, converted, replaced with or into different function groups or bonding structure after the subsequent thermal and wet processes. In one embodiment, the substrate temperature in the process chamber is maintained at a range between about room temperature to about 200 degrees Celsius, such as about less than 100 degrees Celsius, for example about 30 degrees Celsius and about 80 degrees Celsius.

The dielectric material precursor may be supplied into the processing chamber at a flow rate between about 1 sccm and about 5000 sccm. The processing precursors may be supplied into the processing chamber at a flow rate between about 1 sccm and about 1000 sccm. Alternatively, the gas mixture supplied during processing may also be controlled at a flow ratio of dielectric material precursor to processing precursor of between about 0.1 and about 100. The process pressure is maintained at between about 0.10 Torr to about 10 Torr, for example, about 0.1 Torr and about 1 Torr, such as about 0.5 Torr and about 0.7 Torr.

One or more inert gases may also be included with the gas mixture provided to the process chamber 100. The inert gas may include, but not limited to, noble gas, such as Ar, He, Xe, and the like. The inert gas may be supplied to the processing chamber at a flow ratio of between about 1 sccm and about 50000 sccm.

A RF power is applied to maintain the plasma during deposition. The RF power is provided between about 100 kHz and about 100 MHz, such as about 350 kHz or about 13.56 MHz. Alternatively, a VHF power may be utilized to provide a frequency up to between about 27 MHz and about 200 MHz. In one embodiment, the RF power may be supplied between about 1000 Watt and about 10000 Watt. The spacing of the substrate to the top of the processing chamber 100 may be controlled in accordance with the substrate dimension. In one embodiment, the processing spacing is controlled between about 100 mils and about 5 inches.

In one embodiment, the dielectric material 402 formed on substrate 202 is a silicon containing material having oxygen atoms, such as SiO2.

At operation 306, after the dielectric material 402 is formed on the substrate 202, the substrate 202 is cured and/or thermally processed to bake the dielectric material 402, forming a cured dielectric material 403, as shown in FIG. 4C. The curing/baking process removes the moisture from the dielectric material 402 so as to form a solid phase cured dielectric material 403, as shown in FIG. 4C. As the dielectric material 402 is cured, moisture and solvent in the dielectric material 402 is driven out, resulting in the dielectric material 402 to reflow, forming a substantially planar surface on the substrate 202. In one embodiment, the curing process performed at operation 306 may be executed on a hot plate, an oven, a heated chamber or suitable tools that may provide sufficient heat to the substrate 202.

In one embodiment, the curing temperature may be controlled at below 400 degrees Celsius, such as below 10 degrees Celsius, for example about between 50 degrees Celsius and 80 degrees Celsius. The curing time may be controlled at between about 1 seconds and about 10 hours.

During the curing process, a processing gas, such as an oxygen containing gas, may be supplied to the substrate surface to assist reacting with the dielectric material 402 with a densified structure. In one example, the oxygen containing gas supplied during the curing process is an O₃ or O₂ gas.

At operation 308, after the curing process, a high pressure annealing process is performed. The annealing process performed at high process pressure, such as greater than 2 bar, may assist densifying and repairing the vacancies in the cured dielectric material 403, forming the dielectric layer 201 with the desired film properties, as shown in FIG. 4D. The annealing process may be performed at a processing chamber, such as the processing chamber 100 depicted in FIG. 1, or other suitable processing chambers, including those that process substrate one at a time.

The high pressure annealing process performed at operation 308 maintains processing pressure at the high-pressure region in a vapor phase, for example in a dry vapor phase that has substantially no liquid droplets present. The processing pressure and temperature is controlled to density the film structures, so as to repair the film defects, driving out impurities and increasing film density. In one example, the high-pressure region 115 is pressurized to a pressure greater than atmosphere, for example greater than about 2 bar. In another example, the high-pressure region 115 is pressurized to a pressure from about 5 to about 100 bars, such as from about 5 to about 75 bars. As the high pressure may efficiently assist densifying the film structure, a relatively low processing temperature, such as less than 500 degrees Celsius, to reduce likelihood of thermal cycle damage to the substrate 202.

During processing, the high-pressure region 115 is maintained at a relatively low temperature, for example, a temperature less than 400 degrees Celsius, such as between about 150 degrees Celsius and about 350 degrees Celsius, by the heaters 154 disposed within the outer chamber body 110. Thus, a low thermal budget to the substrate may be obtained by utilizing the high pressure annealing process along with low temperature regime.

It is believed that the high pressure process may provide a driving force to drive out the dangling bonds in the dielectric layer 201, thus, repairing, reacting and saturating the dangling bonds in the dielectric layer 201 during the annealing process. In one example, an oxygen containing gas, such as O₃ gas, O₂ gas, H₂O, H₂O₂, N₂O, NO₂, CO₂, CO, dry steam, or other suitable gases may be supplied during the annealing process. In one specific example, the oxygen containing gas comprises steam, for example, dry steam. The oxygen elements from the oxygen containing gas during the annealing process may be driven into the dielectric layer 201, altering the bonding structures and removing the atomic vacancies therein, thus, densifying and enhancing lattice structures of the dielectric layer 201. In some examples, inert gas, such as Ar, N₂, He, Kr and the like, may be supplied with the oxygen containing gas. In one embodiment, the oxygen containing gas supplied in the oxygen containing gas mixture is dry steam supplied at a pressure greater than 2 bar.

In one exemplary implementation, a process pressure is regulated at a pressure greater than 2 bar, such as between 5 bar and 100 bar, such as between 20 bar and about 80 bar, for example between about 25 bar and 75 bar. The process temperature may be controlled at greater than 150 degrees Celsius but less than 400 degrees Celsius, such as between about 150 degrees Celsius and about 380 degrees Celsius, such as between about 180 degrees Celsius and about 350 degrees Celsius.

After the annealing process, the dielectric layer 201 has a densified film structure, which provides a relatively robust film structure that provides lower wet etching rate (compared to a porous film structure often having a high wet etching rate). In one example, the wet etching rate of dielectric layer 201 has reduced and slowed from 6.7 to 1.5 greater (the dielectric material 402 prior to annealing v.s. the dielectric layer 201 after annealing) than the wet etching rate for thermally grown oxide, which is known as the more robust film, compared to the film layers formed by a conventional chemical vapor deposition process having relatively more porous structures. Thus, after the high pressure annealing process, the film density of dielectric layer 201 is at least about 3 to 5 times denser than the film density of the dielectric material 402 prior to experiencing the high pressure annealing process.

Thus, methods for forming a material layer in a film stack for manufacturing a photomask in EUV applications are provided. The material layer, such as a dielectric layer, may be thermally treated/annealed by a high pressure annealing process with high process pressure, such as greater than 2 bar. By utilizing such high pressure annealing process, the process temperature may be maintained less than 400 degrees Celsius, thus reducing the thermal budge contributed to the glass substrate where the dielectric layer is formed thereon, providing a good interface management and integration for fabricating a EUV photomask substrate.

While the foregoing is directed to embodiments of the present invention, other and further embodiments of the invention may be devised without departing from the basic scope thereof, and the scope thereof is determined by the claims that follow.

1. A method of forming a dielectric material on a substrate comprising:
supplying an oxygen containing gas mixture on a substrate in a processing chamber, the substrate comprising a dielectric material disposed on an optically transparent silicon containing material;
maintaining the oxygen containing gas mixture in the processing chamber at a process pressure at greater than 2 bar; and
thermally annealing the dielectric material in the presence of the oxygen containing gas mixture.

2. The method of claim 1, wherein supplying the oxygen containing gas mixture further comprises:
maintaining a substrate temperature at less than 400 degrees Celsius.

3. The method of claim 1, wherein oxygen containing gas mixture includes at least an oxygen containing gas selected from a group consisting of O₃ gas, O₂ gas, H₂O, H₂O₂, N₂O, NO₂, CO₂, CO, dry steam.

4. The method of claim 1, wherein oxygen containing gas mixture includes dry steam.

5. The method of claim 1, wherein the optically transparent silicon containing material of the substrate is quartz or glass.

6. The method of claim 1, wherein the process pressure is between about 5 bar and 100 bar.

7. The method of claim 1, wherein the dielectric material is selected from a group consisting of silicon oxide (SiO₂), silicon oxycarbide (SiOC), silicon carbide (SiC), silicon nitride (SiN), silicon oxynitride (SiON), amorphous silicon, and nitrogen containing silicon carbide (SiCN) and high-k materials.

8. The method of claim 7, wherein the high-k material may be selected from a group consisting of hafnium dioxide (HfO₂), zirconium dioxide (ZrO₂), hafnium silicon oxide (HfSiO₂), hafnium aluminum oxide (HfAlO), zirconium silicon oxide (ZrSiO₂), tantalum dioxide (TaO₂), aluminum oxide, aluminum doped hafnium dioxide, bismuth strontium titanium (BST), and platinum zirconium titanium (PZT).

9. The method of claim 7, wherein the dielectric material is a silicon oxide.

10. The method of claim 1, wherein the dielectric material is fabricated to become a photomask reticle.

11. The method of claim 1, further comprising:
curing the dielectric material prior to supplying the oxygen containing gas to the substrate.

12. The method of claim 11, further comprising:
curing the dielectric layer on a plate, an oven or a heated chamber at a temperature below 400 degrees Celsius.

13. The method of claim 1, further comprising:
forming a multiple film stack including repeating layers of molybdenum layer and silicon layer.

14. The method of claim 1, wherein the dielectric material is formed by a flowable chemical vapor deposition process.

15. The method of claim 1, wherein the dielectric material has a higher film density after the thermally annealing.

16. A method for densifying a dielectric layer disposed on a substrate comprising:
thermally treating a dielectric layer disposed on a glass substrate at a pressure greater than 2 bar; and
maintaining a substrate temperature less than 400 degrees Celsius during thermally treating the dielectric layer.

17. The method of claim 16, further comprising:
supplying dry steam to the dielectric layer while thermally treating the dielectric layer.

18. The method of claim 16, wherein the dielectric layer is a silicon oxide layer.

19. The method of claim 16, wherein the dielectric layer has a higher density after thermally treated.

20. A method for densifying a dielectric layer disposed on a substrate comprising:
forming a dielectric layer on a glass substrate by a flowable chemical vapor deposition process;
curing the dielectric layer at a substrate temperature less than 400 degrees Celsius; and
thermally treating the dielectric layer on the glass substrate at a pressure greater than 2 bar while maintaining the substrate temperature less than 400 degrees Celsius.
